(19) United States
(12) Patent Application Publication
(10) Pub. No.: US 2026/0362616 A1
(43) Pub. Date: Nov. 12, 2026

(54) FOLDING PORTABLE DISPLAY DEVICE WITH MAGNETIC HINGE

(71) Applicant: Google LLC, Mountain View, CA (US)

(72) Inventors: Shih Wei Hsiang, New Taipei City (TW); Kuan-hsu Chen, New Taipei City (TW)

(21) Appl. No.: 19/477,134

(22) PCT Filed: May 16, 2023
(86) PCT No.: PCT/US2023/022400

§ 371 Date: Oct. 21, 2025

(51) Int. Cl. H05K 5/02

(52) U.S. Cl. CPC H05K 5/0226

(57) ABSTRACT

An example folding device includes a continuous display, a hinge assembly, and a first assembly. The hinge assembly defines a first hinge axis and a second hinge axis. The hinge assembly includes a first gear defining a first gear axis and a second gear defining a second gear axis. The hinge assembly further includes a first magnetic element and a first arm assembly. The first arm assembly includes a first proximal end rotatably connected to the hinge assembly about the first hinge axis. The first arm assembly further includes a first distal end on which the first magnetic element is positioned. The first assembly is rotatably connected to the hinge assembly about the first gear axis. The first assembly includes a second magnetic element having an opposite pole to the first magnetic element.

### BACKGROUND

Devices that include displays may be referred to as display devices. In general, it may be desirable to increase a size of a display (e.g., the area on which images are displayed) as much as possible. Increasing the size of a display may make the device that includes the display large and unwieldy. For instance, devices with larger displays may not fit in pockets, bags, and the like. One way to increase the size of a display without negatively affecting the portability of the device is to make the device collapsible such that the display can be folded (e.g., in half).

### SUMMARY

In general, aspects of this disclosure are directed to a hinge assembly of a folding device. The hinge assembly may include magnetic elements that enable the folding device to lock in place when the folding device is opened and closed. The magnetic elements may be configured to improve durability, smoothness, flexibility, and alignment of the hinge assembly. For example, in addition to allowing the folding device to open and close fully, smoothly, and securely, the magnetic elements may experience negligible damage and deformation during use. In this way, the techniques of the disclosure may improve the feeling (e.g., how opening and closing the folding device feel to a user), cycling life, open-close force advantages, etc., of a hinge assembly of a folding device.

In some examples, a folding device includes a continuous display, a hinge assembly, and a first assembly. The hinge assembly defines a first hinge axis and a second hinge axis. The hinge assembly includes a first gear defining a first gear axis and a second gear defining a second gear axis. The hinge assembly further includes a first magnetic element and a first arm assembly. The first arm assembly includes a first proximal end rotatably connected to the hinge assembly about the first hinge axis. The first arm assembly further includes a first distal end on which the first magnetic element is positioned. The first assembly is rotatably connected to the hinge assembly about the first gear axis. The first assembly includes a second magnetic element having an opposite pole to the first magnetic element.

The details of one or more examples are set forth in the accompanying drawings and the description below. Other features, objects, and advantages of the disclosure will be apparent from the description and drawings, and from the claims.

### BRIEF DESCRIPTION OF DRAWINGS

FIG. 1 is a schematic diagram illustrating a cross section of an example folding device with a multi-rigid segment flexible display, in accordance with one or more aspects of this disclosure.

FIG. 2 is a schematic diagram illustrating an example folding device with a flexible display in a plurality of folded states, in accordance with one or more aspects of this disclosure.

FIG. 3 is a schematic diagram illustrating components of an example folding device with a hinge assembly, in accordance with one or more aspects of this disclosure.

FIG. 4 is a schematic diagram illustrating components of an example folding device with a hinge assembly, in accordance with one or more aspects of this disclosure.

FIG. 5A is a schematic diagram illustrating an example folding device in a fully open state, in accordance with one or more aspects of this disclosure.

FIG. 5B is a schematic diagram illustrating an example folding device in a fully closed state, in accordance with one or more aspects of this disclosure.

FIG. 6 is a schematic diagram illustrating components of one side of an example folding device with a hinge assembly, in accordance with one or more aspects of this disclosure.

FIG. 7A is a graph illustrating a range of torques imparted by magnetic elements of an example folding device, in accordance with one or more aspects of this disclosure.

FIG. 7B is a graph illustrating the relationship between magnetic attraction force and distance of an example folding device, in accordance with one or more aspects of this disclosure in accordance with one or more aspects of this disclosure.

### DETAILED DESCRIPTION

In general, this disclosure is directed to folding devices that include foldable continuous displays with a supported span. A folding device may include at least two assemblies (e.g., panels) and a mechanism configured to allow the assemblies to be moved into a collapsed state in which the device is considered closed and an expanded state in which the device is considered open. When the device is in the expanded state, a display may be visible and may cover at least a portion of an inner surface of all of the assemblies. As such, the device may be considered to be a continuous display (i.e., because it continues across or spans a boundary between the assemblies). By utilizing such a folding device, the device may include a display with a relatively large length and/or width (e.g., display area) without overly increasing a length and/or width of the device when in the collapsed state. In this way, the “pocketability” of large-screen portable devices may be improved.

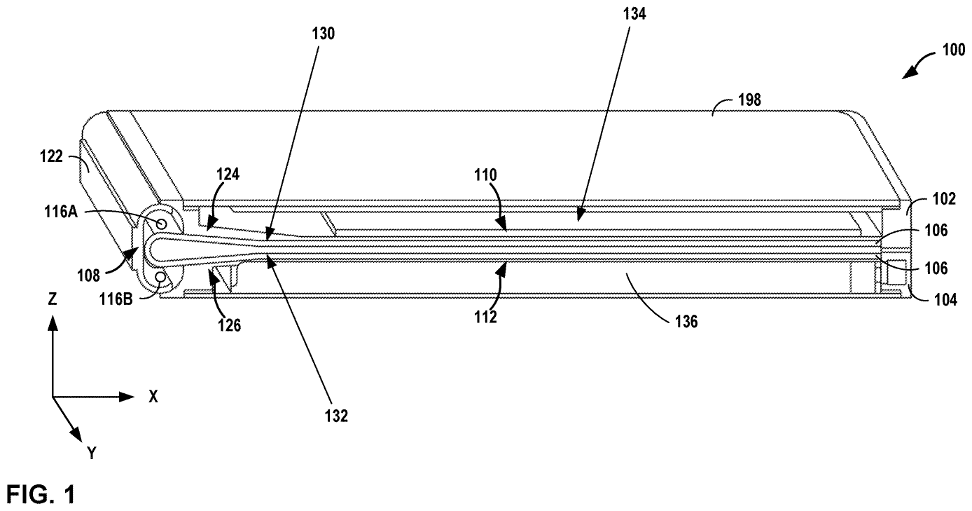

FIG. 1 is a schematic diagram illustrating a cross section of a folding device 100 with a multi-rigid segment flexible display, in accordance with one or more aspects of this disclosure. Examples of device 100 include foldable mobile computing devices such as foldable smart phones, foldable tablets, foldable e-readers, foldable gaming systems, or any other foldable portable device that includes a display.

As shown in FIG. 1, device 100 includes a first assembly 102, second assembly 104, continuous display 106, and hinge assembly 122. Each of first assembly 102 and second assembly 104 may include an inner surface and an outer surface. The outer surface of first assembly 102 may be visible when looking down at device 100 in the z-axis and the outer surface of second assembly 104 may be visible when looking up at device 100 in the z-axis. The inner surfaces of first assembly 102 and second assembly 104 may not be externally visible when device 100 is closed.

As shown in FIG. 1, first assembly 102 may include main logic board 134 and second assembly 104 may include battery 136. This is merely one example arrangement of components amongst first assembly 102 and/or second assembly 104; other arrangements are possible. For instance, both first assembly 102 and second assembly 104 may include respective batteries.

Continuous display 106 may be capable of rendering data into images viewable by a user of device 100. For example, continuous display 106 may include a matrix of pixels that are individually controllable. Examples of continuous display 106 include, but are not limited to, liquid crystal displays (LCD), light emitting diode (LED) displays, organic light-emitting diode (OLED) displays, micro light-emitting diode (microLED) displays, or similar monochrome or color displays capable of outputting visible information to a user of device 100. Continuous display 106 may span hinge assembly 122 from first assembly 102 to second assembly 104.

In some examples, device 100 may include one or more displays in addition to continuous display 106. For instance, as shown in FIG. 1, device 100 may include a first additional display on the outer surface of first assembly 102 (e.g., display 198). In some examples, device 100 may further include a second additional display on the outer surface of second assembly 104.

One or more of continuous display 106, the first additional display, and/or the second additional display may be presence-sensitive displays. In some examples, a presence sensitive display may detect an object at and/or near a screen. As one example range, a presence-sensitive display may detect an object, such as a finger or stylus that is within 2 inches of the screen. The presence-sensitive display may determine a location (e.g., an (x, y) coordinate) of a screen at which the object was detected. In another example range, a presence-sensitive display may detect an object within six inches of the screen. Other ranges are also possible. The presence-sensitive display may determine the location of the screen selected by a user's finger using capacitive, inductive, and/or optical recognition techniques. In some examples, presence sensitive display also provides output to a user using tactile, audio, or video stimuli.

As shown in the example of FIG. 1, continuous display 106 includes first rigid segment 110 attached to first assembly 102 (e.g., positioned on the inner surface of first assembly 102 and coplanar with the inner surface of first assembly 102), flexible segment 108, and second rigid segment 112 attached to second assembly 104 (e.g., positioned on the inner surface of second assembly 104 and coplanar with the inner surface of first assembly 102). As further shown in the example of FIG. 1, flexible segment 108 includes rigid segment 124 connecting rigid segment 110 to flexible segment 108 and rigid segment 126 connecting rigid segment 112 to flexible segment 108. When device 100 is fully open, rigid segment 124 may be coplanar with the inner surface of first assembly 102 and rigid segment 126 may be coplanar with the inner surface of second assembly 104. However, when device 100 is fully closed, rigid segment 124 may not be coplanar with the inner surface of first assembly 102 and rigid segment 126 may not be coplanar with the inner surface of second assembly 104. Rigid segment 124 may be articulable relative to rigid segment 110 at hinge point 130. Rigid segment 126 may be articulable relative to rigid segment 112 at hinge point 132.

Rigid segments 110 and 112 may be referred to as primary rigid segments while rigid segments 124 and 126 may be referred to as secondary rigid segments. In some examples, a width (e.g., in the x-direction) of the primary rigid segments may be substantially larger than a width of the secondary rigid segments. For instance, a width of rigid segment 124 may be less than or equal to a quarter (25%) of a width of rigid segment 110. Similarly, a width of rigid segment 126 may be less than or equal to a quarter (25%) of a width of rigid segment 112.

The secondary rigid segments may be articulable relative to neighboring primary rigid segments. As one example, rigid segment 124 may be articulable relative to rigid segment 110 at hinge point 130. As another example, rigid segment 126 may be articulable relative to rigid segment 112 at hinge point 132. In some examples, the articulation points between secondary rigid segments and primary rigid segments (e.g., hinge points 130 and 132) may have large radii and limited movement as compared to the radius and movement of primary flexible segment 108. As one example, rigid segment 124 may be configured to articulate at most 45 degrees relative to rigid segment 110. As another example, rigid segment 126 may be configured to articulate at most 45 degrees relative to rigid segment 112.

Primary flexible segment 108 may connect the rigid segments of one side of device 100 to the rigid segments of the other side of device 100. For instance, as shown in FIG. 1, primary flexible segment 108 may connect rigid segment 124 to rigid segment 126. Primary flexible segment 108 may be configured to fold at least 180 degrees (e.g., to facilitate closure of device 100).

Device 100 may include one or more supporting plates (e.g., backer plates) configured to render segments of continuous display 106 flexible or rigid. The supporting plates may be positioned between emissive elements of continuous display 106 (e.g., OLEDs) and the inner surfaces of first assembly 102 and second assembly 104.

In some examples, device 100 may include respective supporting plates for segments of continuous display 106. For instance, the one or more supporting plates may include a first supporting plate attached to first rigid segment 110, a second supporting plate attached to second rigid segment 112, a third supporting plate attached to rigid segment 124, and/or a fourth supporting plate attached to rigid segment 126.

In some examples, the one or more supporting plates may include a respective supporting plate for each of first assembly 102 and second assembly 104 that support segments of continuous display 106 on the respective assembly. For instance, the one or more supporting plates may include a first supporting plate attached to first rigid segment 110 and rigid segment 124 that is configured to permit bending between first rigid segment 110 and rigid segment 124, and a second supporting plate attached to second rigid segment 112 and rigid segment 126 that is configured to permit bending between second rigid segment 112 and rigid segment 126.

In some examples, the one or more supporting plates may include a single supporting plate that is attached to segments of continuous display 106 on both first assembly 102 and second assembly 104. For instance, the one or more supporting plates may include a single supporting plate attached to primary flexible segment 108 and all primary and secondary rigid segments (e.g., first rigid segment 110, second rigid segment 112, rigid segment 124 and rigid segment 126). The single supporting plate may be configured to permit bending between the segments. To permit bending between segments, a supporting plate may be etched and/or perforated at a boundary between adjacent segments.

In general, hinge assembly 122 may be relatively complex and expensive. For example, hinge assembly 122 may include multiple components, such as gears, springs, and bearings, that need to conform to precise specifications to ensure that hinge assembly 122 functions properly. Additionally, hinge assembly 122 may be susceptible to damage. For example, dirt, dust, and other debris can accumulate in hinge assembly 122, causing it to become stiff or difficult to move. Hinge assembly 122 may also experience wear and tear due to repeated use, causing hinge assembly 122 to become loose, wobbly, or misaligned. Misalignment of hinge assembly 122 may lead to damage to display 106 or other components of device 100.

In accordance with techniques of this disclosure, device 100 may include magnetic elements configured to impart forces that improve one or more of the feeling, auto-locking, cycling life, or open-close force advantages of device 100. The magnetic elements may also improve the durability, smoothness, flexibility, and alignment of the hinge assembly. For example, in addition to allowing device 100 to open and close fully, smoothly, and securely, the magnetic elements may experience negligible damage and deformation during use.

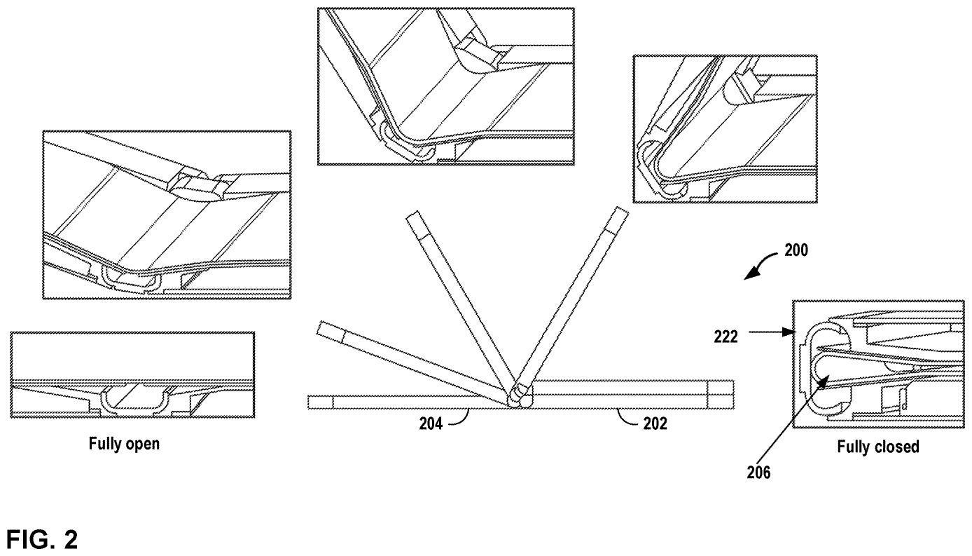

FIG. 2 is a schematic diagram illustrating a folding device 200 with a flexible continuous display 206 in a plurality of folded states, in accordance with one or more aspects of this disclosure. Device 200 may be an example of device 100 shown in FIG. 1. As shown in FIG. 2, a portion of display 206 resides within a hinge assembly 222 while device 200 is closed. As further shown in FIG. 2, when folding device 200 is fully open, an inner surface of a first assembly 202 is coplanar with an inner surface of a second assembly 204.

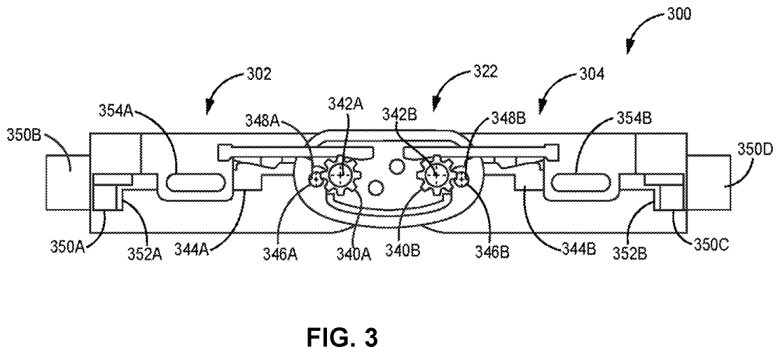

FIG. 3 is a schematic diagram illustrating components of a folding device 300 with a hinge assembly 322, in accordance with one or more aspects of this disclosure. Device 300 may be an example of device 100 shown in FIG. 1. As described in greater detail below, the components of device 300 may be configured to improve one or more of the feeling, auto-locking, cycling life, or open-close force advantages of device 300.

Hinge assembly 322 may be an example of hinge assembly 122 shown in FIG. 1. Hinge assembly 322 may include a first gear 340A that defines a first gear axis 342A and a second gear 340B that defines a second gear axis 342B. A first assembly 302 may be rotatably connected to hinge assembly 322 about first gear axis 342A. A second assembly 304 may be rotatably connected to hinge assembly 322 about second gear axis 342B.

A first arm assembly 344A and a second arm assembly 344B may be rotatably connected to hinge assembly 322. For example, a first proximal end 346A of first arm assembly 344A may be rotatably connected to hinge assembly 322 about a first hinge axis 348A defined by hinge assembly 322, and a second proximal end 346B of second arm assembly 344B may be rotatably connected to hinge assembly 322 about a second hinge axis 348B defined by hinge assembly 322.

Hinge assembly 322 may be configured to synchronize movement of first assembly 302 and second assembly 304 as device 300 is moved between the opened state and the closed state. For example, first gear 340A may mesh with second gear 340B to synchronize the movement of first assembly 302 and second assembly 304. In another example, hinge assembly 322 may include one or more auxiliary gears (e.g., a first auxiliary gear and a second auxiliary gear) that mesh with first gear 340A and second gear 340B (such that first gear 340A and second gear 340B are indirectly mechanically coupled) to synchronize the movement of first assembly 302 and second assembly 304.

Device 300 may include magnetic elements, such as a first magnetic element 350A, a second magnetic element 350B, a third magnetic element 350C, and a fourth magnetic element 350D. Two or more of magnetic elements 350A-350D may impart a force that resist rotation (e.g., a change in angle between first assembly 302 and second assembly 304) of device 300, thereby improving the feeling, cycling life, open-close force advantages, etc., of hinge assembly 322.

First magnetic element 350A may be mounted or otherwise positioned on a first distal end 352A of first arm assembly 344A. First assembly 302 may include second magnetic element 350B (e.g., second magnetic element 350B may be located in first assembly 302). Second magnetic element 350B may have an opposite pole to first magnetic element 350A. Thus, second magnetic element 350B and first magnetic element 350A may impart a first force of magnetic attraction. The first force may be associated with an open-close force advantage of device 300.

Third magnetic element 350C may be mounted or otherwise positioned on a second distal end 352B of second arm assembly 344B. Second assembly 304 may include fourth magnetic element 350D (e.g., fourth magnetic element 350D may be located in second assembly 304). Fourth magnetic element 350D may have an opposite pole to third magnetic element 350C. Thus, fourth magnetic element 350D and third magnetic element 350C may impart a second force of magnetic attraction. The second force may be associated with an open-close force advantage of device 300.

As shown in FIG. 3, first gear axis 340A is not coaxial with first hinge axis 348A. and second gear axis 340B is not coaxial with second hinge axis 348B. As a result, when the angle between first assembly 302 and second assembly 304 changes, the distance between first magnetic element 350A and second magnetic element 350B and the distance between third magnetic element 350C and fourth magnetic element 350D may change by a corresponding amount. In general, magnetic force is inversely proportional to distance. Thus, when the angle between first assembly 302 and second assembly 304 changes, the first force of magnetic attraction and the second force of magnetic attraction may change by a corresponding amount. In some examples, the first force and the second force may be non-linearly related to the angle between first assembly 302 and second assembly 304.

In some examples, a first hinge plate 354A may be connected to first assembly 302 and mechanically coupled to first arm assembly 344A, and a second hinge plate 354B may be connected to second assembly 304 and mechanically coupled to second arm assembly 344B. First hinge plate 354A may be configured to slide relative to first arm assembly 344A. Second hinge plate 354B may be configured to slide relative to second arm assembly 344B.

For example, first hinge plate 354A may define a first channel (e.g., a slot) in which a portion of first arm assembly 344A is disposed. Second hinge plate 354B may define a second channel in which a portion of second arm assembly 344B is disposed.

The portion of first arm assembly 344A may slide within the first channel when the angle between first assembly 302 and second assembly 304 changes. The portion of second arm assembly 344B may slide within the second channel when the angle between first assembly 302 and second assembly 304 changes. When the portion of first arm assembly 344A contacts a perimeter of the first channel, first hinge plate 354A may guide the movement of first arm assembly 344A in relation to first assembly 302. When the portion of second arm assembly 344B contacts a perimeter of the second channel, second hinge plate 354B may guide the movement of second arm assembly 344B in relation to second assembly 304. In this way, first hinge plate 354A and second hinge plate 354B may facilitate the change in distance between magnetic elements 350A-350D while guiding and synchronizing the movements of first assembly 302 and second assembly 304.

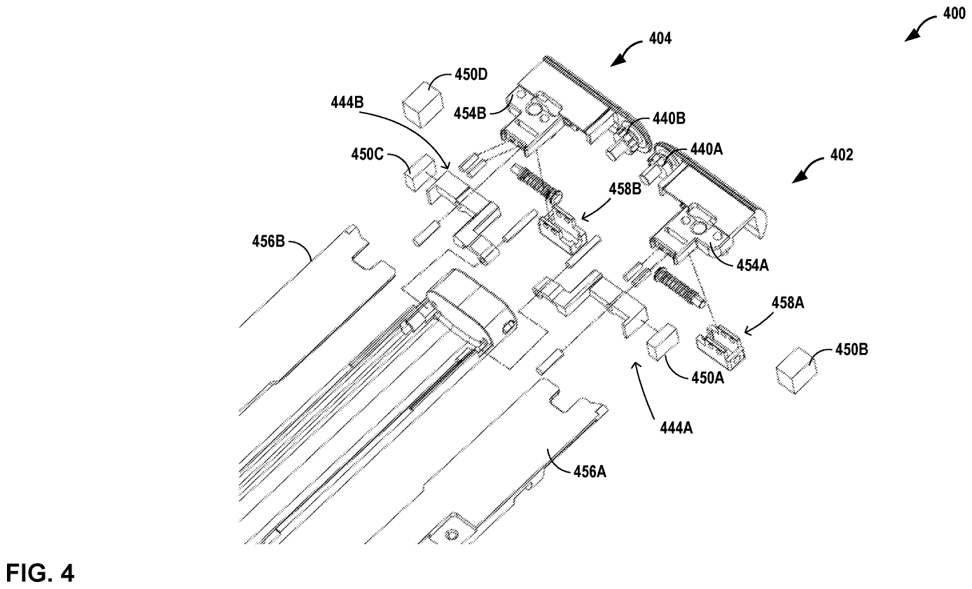

FIG. 4 is a schematic diagram illustrating components of a folding device 400 with a hinge assembly 422, in accordance with one or more aspects of this disclosure. Folding device 400 may be an example of folding device 100 shown in FIG. 1. As shown in FIG. 4, folding device 400 includes a first assembly 402, a second assembly 404, a first gear 440A, a second gear 440B, a first arm assembly 444A, a second arm assembly 444B, a first magnetic element 450A, a second magnetic element 450B, a third magnetic element 450C, a fourth magnetic element 450D, a first hinge plate 454A, and a second hinge plate 454B.

In some examples, device 400 may include a first supporting plate 456A and a second supporting plate 456B. First supporting plate 456A may be connected to first assembly 402, and second supporting plate 456B may be connected to second assembly 404. First supporting plate 456A and second supporting plate 456B may be configured to be collapsible. For example, contact between supporting plates 456 and hinge assembly 422 may result in deployment of supporting plates 456 as device 400 is opened. While hinge assembly 422 may cause deployment (e.g., raising, lifting, etc.) of collapsible supporting plates 456, it may be desirable for collapsible supporting plates 456 to easily un-deploy (e.g., lower, collapse, etc.) when folding device 400 is closed.

Device 400 may include one or more bias modules, such as a first bias module 458A and a second bias module 458B. For instance, device 400 may include first bias module 458A located in first assembly 402 and second bias module 458B located in second assembly 404. First bias module 458A may be connected to first supporting plate 456A, and second bias module 458B may be connected to second supporting plate 456B. First bias module 458A may be configured to facilitate articulation of first supporting plate 456A relative to first assembly 402. As also shown in FIG. 4, second bias module 458B may be configured to facilitate articulation of second supporting plate 456B relative to second assembly 404.

In some examples, first bias module 458A may be configured to bias supporting plates 456A in a collapsed (e.g., un-deployed) position, and second bias module 458B may be configured to bias supporting plate 456B in a collapsed position. First bias module 458A may be configured to bias first supporting plate 456A in the collapsed position and second bias module 458B may be configured to bias second supporting plate 456B in the collapsed position. In some examples, device 400 may include a single bias module per side (e.g., one bias module in each of first assembly 402 and second assembly 404). In some examples, device 400 may include multiple bias module per side (e.g., two or more bias modules in each of first assembly 402 and second assembly 404). Examples of first bias module 458A and second bias module 458B include spring loaded pins, hydraulic pistons, and the like.

As noted above, first bias module 458A and second bias module 458B may respectively bias first supporting plate 456A and first support plate 456B in the undeployed position. The force imparted on first supporting plate 456A and first support plate 456B by hinge assembly 422 may be sufficient to overcome the force imparted on collapsible supporting plates 456 by first bias module 458A and second bias module 458B. However, as device 400 transitions to the closed position, first bias module 458A and second bias module 458B may respectively pull collapsible first supporting plate 456A and first support plate 456B down into the collapsed position.

As shown in FIG. 4, hinge assembly 422 may be positioned within and substantially covered by the housing of first assembly 402 and second assembly 404. In this way, first assembly 402 and second assembly 404 may prevent ingress of dust and other materials into hinge assembly 422 that may otherwise impair the functioning of hinge assembly 422. In addition, the housing of first assembly 402 and second assembly 404 may obstruct a view of hinge assembly 422 such that a user of folding device 400 cannot see components within hinge assembly 422.

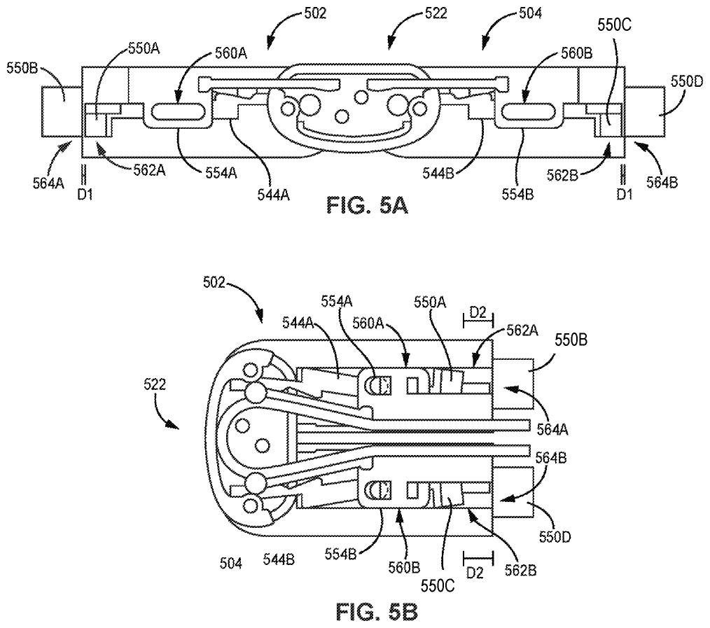

FIGS. 5A-5B are schematic diagrams illustrating a folding device 500 having a hinge assembly 522 in a plurality of states in accordance with one or more aspects of this disclosure. Specifically, FIG. 5A illustrates device 500 in a fully open state, and FIG. 5B illustrates device 500 in a fully closed state. Device 500 may be an example of device 100 shown in FIG. 1.

As shown in FIGS. 5A-5B, device 500 includes magnetic elements, such as a first magnetic element 550A, a second magnetic element 550B, a third magnetic element 550C, and a fourth magnetic element 550D. When device 500 is in a fully open state, the distance between first magnetic element 550A and second magnetic element 550B may be a first distance (labeled as “D1”). When device 500 is in a fully closed state (or any other folded state, such as an intermediate folded state), the distance between first magnetic element 550A and second magnetic element 550B may be a second distance (labeled as “D2”), where the first distance is different from the second distance.

The configuration of third magnetic element 550C and fourth magnetic element 550D may be similar to the configuration of first magnetic element 550A and second magnetic element 550B. For example, when device 500 is in a fully open state, the distance between third magnetic element 550C and fourth magnetic element 550D may be the first distance. When device 500 is in a fully closed state (or any other folded state, such as an intermediate folded state), the distance between third magnetic element 550C and fourth magnetic element 550D may be the second distance.

In some examples, the first distance may be less than the second distance. In those examples, the force between first magnetic element 550A and second magnetic element 550B and the force between third magnetic element 550C and fourth magnetic element 550D when device 500 is in a fully open state may be greater than the force between first magnetic element 550A and second magnetic element 550B and the force between third magnetic element 550C and fourth magnetic element 550D when device 500 is in a fully closed state.

A first hinge plate 554A may define a first channel 560A in which a portion of first arm assembly 544A is disposed. Second hinge plate 554B may define a second channel 560B in which a portion of second arm assembly 544B is disposed. The portion of first arm assembly 544A may slide within the first channel when the angle between first assembly 502 and second assembly 504 changes. The portion of second arm assembly 544B may slide within the second channel when the angle between first assembly 502 and second assembly 504 changes.

In some examples, a distal surface 562A of a first magnetic element 550A and a proximal surface 564A of a second magnetic element 550B may be parallel when device 500 is fully opened. Similarly, a distal surface 562B of a third magnetic element 550C and a proximal surface 564B of a fourth magnetic element 550D may be parallel when device 500 is fully opened.

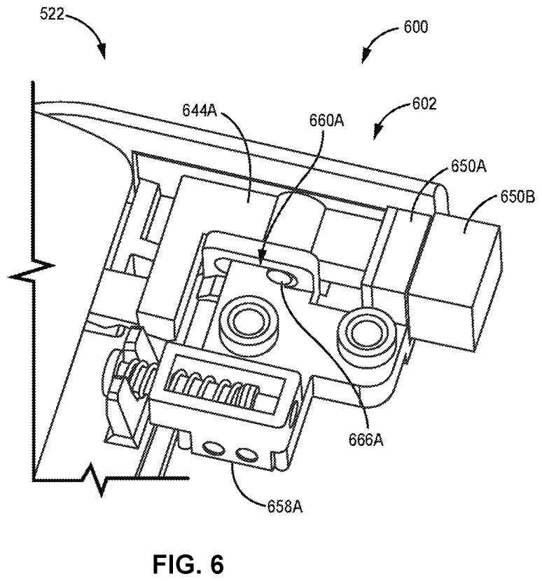

FIG. 6 is a schematic diagram illustrating components of one side of a folding device 600 with a hinge assembly 622, in accordance with one or more aspects of this disclosure, Folding device 600 may be an example of folding device 100 shown in FIG. 1. As shown in FIG. 6, folding device 600 includes a first assembly 602, a first arm assembly 644A, a first magnetic element 650A, a second magnetic element 650B, a first hinge plate 654A, and a first bias module 658A.

As described above, first binge plate 654A may define a first channel 660A in which a portion of first arm assembly 644A is disposed. For example, first arm assembly 644A may include a first pin 666A, and first pin 666A may be at least partially disposed within first channel 660A. First pin 666A may slide within first channel 644A. When first pin 666A contacts a perimeter of first channel 660A, first hinge plate 654A may guide the movement of first arm assembly 644A in relation to first assembly 602. In this way, first hinge plate 654A may facilitate the change in distance between magnetic elements 650A and 650B.

Although not shown, second assembly 604 of folding device 600 may be configured in a similar manner. For example, a second arm assembly 644B may include a second pin 666B, and second pin 666B may be at least partially disposed within a second channel 660B. second pin 666B may slide within second channel 660B. When second pin 666B contacts a perimeter of second channel 660B, second hinge plate 654B may guide the movement of second arm assembly 644B in relation to second assembly 604. In this way, second hinge plate 654B may facilitate the change in distance between magnetic elements 650C and 650D.

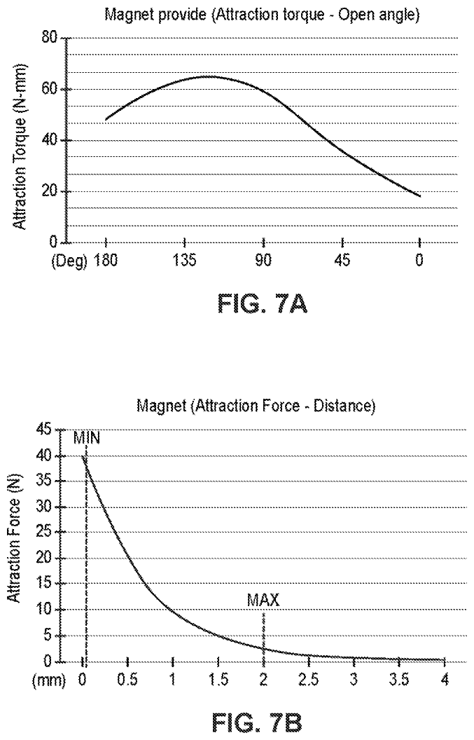

FIG. 7A is a graph illustrating the torque imparted by a hinge assembly in accordance with one or more aspects of this disclosure. FIG. 7A is primarily described with respect to hinge assembly 322 shown in FIG. 3. However, it should be understood that the description of FIG. 7A may apply equally to any other hinge assembly described herein.

The biasing torque imparted by magnetic elements 350A-350D may vary based on the angle between first assembly 302 and second assembly 304. For example, as shown in FIG. 7A, magnetic elements 350A-350D may impart a biasing torque of about 50 Newton-millimeters (N*mm) when the angle between first assembly 302 and second assembly 304 is about 180 degrees (e.g., when device 300 is fully open). The biasing torque imparted by magnetic elements 350A-350D may increase from about 50 N*mm to about 65 N*mm as the angle between first assembly 302 and second assembly 304 changes from about 180 degrees to about 120 degrees. The biasing torque imparted by magnetic elements 350A-350D may decrease from about 65 N*mm to about 20 N*mm as the angle between first assembly 302 and second assembly 304 changes from about 120 degrees to about 0 degrees (e.g., when device 300 is fully closed).

FIG. 7B is a graph illustrating an example relationship between magnetic attraction force and distance, in accordance with one or more aspects of this disclosure. FIG. 7B is primarily described with respect to hinge assembly 322 shown in FIG. 3. However, it should be understood that the description of FIG. 7B may apply equally to any other hinge assembly described herein.

In general, the magnetic force between two magnetic objects may depend on the strength of their magnetic fields and the distance between them. According to the inverse square law, the magnetic force is inversely proportional to the square of the distance between the objects. Thus, as the distance between the objects increases, the magnetic force decreases, and as the distance between the objects decreases, the magnetic force increases. Accordingly, the forces imparted by magnetic elements 350A-350D may be non-linearly related to an angle between first assembly 302 and second assembly 304.

As described above, the distance between one or more pair of magnetic elements of device 300 may change based on an angle between first assembly 302 and second assembly 304. In the example of FIG. 7B, the vertical line labeled “MIN” indicates a minimum distance between one or more pairs of magnetic elements (e.g., first magnetic element 350A and second magnetic element 350B, third magnetic element 350C and fourth magnetic element 350D, etc.), and the vertical line labeled “MAX” indicates a maximum distance between one or more pairs of magnetic elements. The minimum distance between the one or more pairs of magnetic elements may occur when the angle between first assembly 302 and second assembly 304 is about 120 degrees. The maximum distance between the one or more pairs of magnetic elements may occur when the angle between first assembly 302 and second assembly 304 is about 0 degrees.

The following numbered example may illustrate one or more aspects of this disclosure:
Example 1: A folding device includes a continuous display; a hinge assembly defining a first hinge axis and a second hinge axis, wherein the hinge assembly includes: a first gear defining a first gear axis; and a second gear defining a second gear axis; a first magnetic element; a first arm assembly includes a first proximal end rotatably connected to the hinge assembly about the first hinge axis; and a first distal end on which the first magnetic element is positioned; and a first assembly rotatably connected to the hinge assembly about the first gear axis, wherein the first assembly includes a second magnetic element having an opposite pole to the first magnetic element.
Example 2: The folding device of example 1, wherein a distal surface of the first magnetic element and a proximal surface of the second magnetic element are parallel when the folding device is fully opened.
Example 3: The folding device of example 1, further includes a first hinge plate connected to the first assembly and mechanically coupled to the first arm assembly, wherein the first hinge plate is configured to slide relative to the first arm assembly.
Example 4: The folding device of example 1, wherein the first magnetic element and the second magnetic element impart a first force associated with an open-close force advantage of the folding device, and wherein the first force is non-linearly related to an angle between the first assembly and the second assembly.
Example 5: The folding device of example 1, further includes a first supporting plate connected to the first assembly; a first bias module, connected to the first supporting plate, configured to facilitate articulation of the first supporting plate relative to the first assembly; a second supporting plate connected to the second assembly; and a second bias module, connected to the second supporting plate, configured to facilitate articulation of the second supporting plate relative to the second assembly.
Example 6: The folding device of example 5, wherein the first bias module includes a first spring loaded pin, and wherein the second bias module includes a second spring loaded pin.
Example 7: The folding device of example 1, further includes a third magnetic element; a second arm assembly includes a second proximal end rotatably connected to the hinge assembly about the second hinge axis; and a second distal end on which the third magnetic element is positioned; and a second assembly rotatably connected to the hinge assembly about the second gear axis, wherein the second assembly includes a fourth magnetic element having an opposite pole to the third magnetic element, and wherein the continuous display spans the hinge assembly from the first assembly to the second assembly.
Example 8: The folding device of example 7, wherein a distal surface of the third magnetic element and a proximal surface of the fourth magnetic element are parallel when the folding device is fully opened.
Example 9: The folding device of example 7, further includes a second hinge plate connected to the second assembly and mechanically coupled to the second arm assembly, wherein the second hinge plate is configured to slide relative to the second arm assembly.
Example 10: The folding device of example 7, wherein the third magnetic element and the fourth magnetic element impart a second force associated with the open-close force advantage of the folding device, and wherein the second force is non-linearly related to an angle between the first assembly and the second assembly.
Example 11: The folding device of example 7, further includes a second supporting plate connected to the second assembly; and a second bias module, connected to the second supporting plate, configured to facilitate articulation of the second supporting plate relative to the second assembly.
Example 12: The folding device of example 11, wherein the second bias module includes a second spring loaded pin.
Example 13: The folding device of example 7, wherein the hinge assembly includes a first auxiliary gear and a second auxiliary gear, wherein the first auxiliary gear and the second auxiliary gear are configured to mesh with the first gear and the second gear to synchronize movement of the first assembly and the second assembly.
Example 14: The folding device of example 1, wherein the continuous display includes an organic light-emitting diode (OLED) display or a micro light-emitting diode display.

Various aspects have been described in this disclosure. These and other aspects are within the scope of the following claims.

1. A folding device comprising:
a continuous display;
a hinge assembly defining a first hinge axis and a second hinge axis, wherein the hinge assembly comprises:
a first gear defining a first gear axis; and
a second gear defining a second gear axis;
a first magnetic element;
a first arm assembly comprising:
a first proximal end rotatably connected to the hinge assembly about the first hinge axis; and
a first distal end on which the first magnetic element is positioned; and
a first assembly rotatably connected to the hinge assembly about the first gear axis, wherein the first assembly comprises a second magnetic element having an opposite pole to the first magnetic element.

2. The folding device of claim 1, wherein a distal surface of the first magnetic element and a proximal surface of the second magnetic element are parallel when the folding device is fully opened.

3. The folding device of claim 1, further comprising: a first hinge plate connected to the first assembly and mechanically coupled to the first arm assembly, wherein the first hinge plate is configured to slide relative to the first arm assembly.

4. The folding device of claim 1, wherein the first magnetic element and the second magnetic element impart a first force associated with an open-close force advantage of the folding device, and wherein the first force is non-linearly related to an angle between the first assembly and the second assembly.

5. The folding device of claim 1, further comprising:
a first supporting plate connected to the first assembly;
a first bias module, connected to the first supporting plate, configured to facilitate articulation of the first supporting plate relative to the first assembly;
a second supporting plate connected to the second assembly; and
a second bias module, connected to the second supporting plate, configured to facilitate articulation of the second supporting plate relative to the second assembly.

6. The folding device of claim 5, wherein the first bias module comprises a first spring loaded pin, and wherein the second bias module comprises a second spring loaded pin.

7. The folding device of claim 1, further comprising:
a third magnetic element;
a second arm assembly comprising:
a second proximal end rotatably connected to the hinge assembly about the second hinge axis; and
a second distal end on which the third magnetic element is positioned; and
a second assembly rotatably connected to the hinge assembly about the second gear axis, wherein the second assembly comprises a fourth magnetic element having an opposite pole to the third magnetic element, and wherein the continuous display spans the hinge assembly from the first assembly to the second assembly.

8. The folding device of claim 7, wherein a distal surface of the third magnetic element and a proximal surface of the fourth magnetic element are parallel when the folding device is fully opened.

9. The folding device of claim 7, further comprising:
a second hinge plate connected to the second assembly and mechanically coupled to the second arm assembly, wherein the second hinge plate is configured to slide relative to the second arm assembly.

10. The folding device of claim 7, wherein the third magnetic element and the fourth magnetic element impart a second force associated with the open-close force advantage of the folding device, and wherein the second force is non-linearly related to an angle between the first assembly and the second assembly.

11. The folding device of claim 7, further comprising:
a second supporting plate connected to the second assembly; and
a second bias module, connected to the second supporting plate, configured to facilitate articulation of the second supporting plate relative to the second assembly.

12. The folding device of claim 11, wherein the second bias module comprises a second spring loaded pin.

13. The folding device of claim 7, wherein the hinge assembly comprises a first auxiliary gear and a second auxiliary gear, wherein the first auxiliary gear and the second auxiliary gear are configured to mesh with the first gear and the second gear to synchronize movement of the first assembly and the second assembly.

14. The folding device of claim 1, wherein the continuous display comprises an organic light-emitting diode (OLED) display or a micro light-emitting diode display.
